(19) United States
(12) Patent Application Publication
(10) Pub. No.: US 2010/0028179 A1
(43) Pub. Date: Feb. 4, 2010

(54) CHEMICAL LIQUID SUPPLYING APPARATUS

(75) Inventor: Takeo Yajima, Tokyo (JP)

Correspondence Address: MCCORMICK, PAULDING & HUBER LLP, CITY PLACE II, 185 ASYLUM STREET, HARTFORD, CT, 06103, US

(73) Assignee: Koganei Corporation, Tokyo (JP)

(21) Appl. No.: 12/534,190

(22) Filed: Aug. 3, 2009

(30) Foreign Application Priority Data
Aug. 4, 2008 (JP) 2008-200672

(51) Int. Cl. F04B 43/08

(52) U.S. Cl. 417/476

(57) ABSTRACT

In a chemical liquid supplying apparatus, discharge accuracy of chemical liquid is enhanced, and durability of a flexible tube is enhanced. By the flexible tube incorporated into a pump housing, an interior of the pump housing is partitioned into a pump chamber, which communicates with a liquid inlet and a liquid outlet, and a drive chamber in which an incompressible, indirect medium is enclosed. Outer surfaces of end portions of the flexible tube are sealed by outer seal members, and their inner surfaces are sealed by inner seal members. Fastening cylindrical bodies disposed in the end portions of the flexible tube are radially expanded by wedge sleeves, whereby the outer and inner seal members are caused to closely contact with the flexible tube.

### CROSS-REFERENCE TO RELATED APPLICATIONS

Applicant hereby claims foreign priority benefits under U.S.C. §119 from Japanese Patent Application No. 2008-200672 filed on Aug. 4, 2008, the contents of which are incorporated by reference herein.

### TECHNICAL FIELD OF THE INVENTION

The present invention relates to a chemical liquid supplying apparatus which discharges chemical liquid such as photoresist liquid.

### BACKGROUND OF THE INVENTION

Before formation of circuit patterns onto a surface of a semiconductor wafer, a polishing processing is performed for flattening the surface of the semiconductor wafer, and when the polishing processing is being performed, polishing liquid is applied onto the surface. When the circuit patterns are formed on the surface after the polishing processing, photoresist or washing liquid is applied onto the surface. As a pump for supplying chemical liquid such as polishing or photoresist liquid to an applied substance, a tube pump having a flexible tube has been used.

The flexible tube is incorporated into a pump housing, thereby partitioning the pump housing into an inner pump chamber and an outer drive chamber. By supplying or exhausting an incompressible, indirect medium to or from the drive chamber, the flexible tube is intended to expand or contract radially and perform a pumping operation. A fixing method of the flexible tube to the pump housing includes a welding type as disclosed in Patent Document 1 (Japanese Patent Application Laid-Open Publication No. 2008-101510), in which both end portions of the flexible tube are deposited or welded to the pump housing, and a fastening type as disclosed in Patent Document 2 (Japanese Patent Application Laid-Open Publication No. 11-117872), in which both end portions of the flexible tube are sandwiched among the pump housing and adaptors fitted into the respective end portions of the flexible tube.

### SUMMARY OF THE INVENTION

When the flexible tube starts to perform the pump operation, an elastically deformable portion of the flexible tube expands or contracts radially and, at this time, the elastically deformable portion becomes deformable longitudinally. Since the both end portions of the flexible tube are fixed to the pump housing, when the flexible tube performs the pump operation, an axial-directional center portion of the flexible tube is most deformed radially, whereby the maximum tension is generated in the flexible tube when the center portion is most crushed (pushed). This tension is exerted in a direction of pulling the both end portions of the flexible tube out of the housing.

To improve a yield of the semiconductor wafer, a high-speed supply of the chemical liquid to the semiconductor wafer has been demanded recently. Also, to downsize a chemical liquid supplying pump without changing a discharge amount of the chemical liquid, shortening length of the flexible tube has been demanded. To attain a high-speed operation and the downsizing of the chemical liquid supplying pump, it is required to make high a fixing strength and a seal property of the both end portions of the flexible tube with respect to the pump housing.

To make high the fixing strength of the both end portions of the flexible tube, the above-mentioned welding type is preferable. However, if this welding type is selected as a fixing method, it is required to make quality of a material of the pump housing identical to that of the flexible tube. For example, if the pump housing and the flexible tube are formed of fluorine resins, the welding type can be used. However, if the pump housing is made of metal instead of a fluorine resin, since metal cannot be welded to a fluorine resin, a tube pump of the welding type cannot be produced.

Meanwhile, in order to use the both end portions of the flexible tube as the fastening types, the both end portions are tapered, and the tapered end portions are intended to be sandwiched among the pump housing and the adaptors. If the flexible tube is made of a resin, a creeping phenomenon occurs in the resin, which results in a gradual decrease in the seal properties of the both end portions. The rubber-made flexible tube is more elastic than a resin, and so is better in seal property than a resin. However, when a tension is exerted on the rubber-made flexible tube during its pumping operation, the end portions sandwiched among the pump housing and the adaptors are made thin due to the tension. For this reason, there is the problem that the fastening type cannot be applied to the chemical liquid supplying pump in which the tensions exerted on the end portions tension become strong.

When the seal property of the flexible tube deteriorates, the incompressible, indirect medium in the drive chamber leaks outside, and external air flows in the drive chamber. Therefore, a correspondence relation between an expanding/contracting amount of the drive chamber and a discharging amount of the chemical liquid flowing from an interior of the flexible tube is lost, which results in deterioration of discharging accuracy of the chemical liquid. Also, if the end portions of the flexible tube are not tightly sandwiched among the pump housing and the adaptors, the flexible tube is offset and released from a fastening portion due to the tension during the pumping operation, which results in deterioration of the discharging accuracy of the chemical liquid. In addition thereto, partially exceeding crushes or folding lines are generated in the flexible tube, which results in deterioration of durability of the flexible tube.

An object of the present invention is to enhance discharging accuracy of chemical liquid in a chemical liquid supplying apparatus with a flexible tube.

Another object of the present invention is to enhance durability of the flexible tube.

A chemical liquid supplying apparatus according to the present invention comprises: a pump housing provided with a liquid inlet and a liquid outlet; a flexible tube incorporated into the pump housing, partitioning a pump chamber communicating with the liquid inlet and outlet, and partitioning a drive chamber in which an incompressible, indirect medium is enclosed between the flexible tube and the pump housing; driving means provided to the pump housing, and expanding and contracting the pump chamber via the incompressible, indirect medium; an outer seal member disposed in an inner surface of the pump housing so as to correspond to an end portion of the flexible tube; a fastening cylindrical body, outside which an inner seal member is provided and which is disposed in the end portion of the flexible tube; and a wedge sleeve inserted inside the fastening cylindrical body from an opening end of the pump housing under the condition that the flexible tube is incorporated into the pump housing and that the fastening cylindrical body is incorporated into the end portion, the wedge sleeve causing the fastening cylindrical body to be radially expanded so as to incline by being centered about an inner end of the fastening cylindrical body, and causing the inner and outer seal members to closely contact with the flexible tube.

The chemical liquid supplying apparatus according to the present invention is such that an outer concave-convex portion is formed in the inner surface of the pump housing so as to correspond to the end portion of the flexible tube, an inner concave-convex portion is formed in the fastening cylindrical body so as to correspond to the outer concave-convex portion, and a folding portion, which is folded by the outer and inner concave-convex portions when the wedge sleeve is inserted inside the fastening cylindrical body, is formed in the flexible tube.

A chemical liquid supplying apparatus according to the present invention comprises: a pump housing provided with a liquid inlet port and a liquid outlet; a flexible tube incorporated into the pump housing, partitioning a pump chamber communicating with the liquid inlet and outlet, and partitioning a drive chamber in which an incompressible, indirect medium is enclosed between the flexible tube and the pump housing; driving means provided to the pump housing, and expanding and contracting the pump chamber via the incompressible, indirect medium; an outer seal member disposed in a fitting hole, which is formed in an inner surface of the pump housing, so as to correspond to an end portion having a straight hole larger in diameter than an elastically deformable portion which is a center portion of the flexible tube, and a taper hole located between the elastically deformable portion and the straight hole; and a fastening cylindrical body having a straight outer circumferential surface corresponding to the straight hole and a taper outer circumferential surface corresponding to the taper hole, an outer circumferential surface of the fastening cylindrical body being provided with an inner seal member, and the fastening cylindrical body being disposed in the end portion of the flexible tube, wherein the flexible tube is fastened between the taper outer circumferential surface and the taper hole, and the straight outer circumferential surface is pushed to the straight hole so that the outer and inner seal members are caused to closely contact with the flexible tube.

The chemical liquid supplying apparatus according to the present invention is such that an outer concave-convex portion is formed in an inner circumferential surface of the pump housing so as to correspond to the end portion of the flexible tube, an inner concave-convex portion is formed in the fastening cylindrical body so as to correspond to the outer concave-convex portion, and a folding portion, which is folded by the outer and inner concave-convex portions, is formed in the flexible tube.

The chemical liquid supplying apparatus according to the present invention further comprises a wedge sleeve inserted inside the fastening cylindrical body from an opening end of the pump housing under the condition that the flexible tube is incorporated into the pump housing and that the fastening cylindrical body is incorporated into the end portion, wherein the wedge sleeve causes the fastening cylindrical body to be radially expanded so as to incline by being centered about an inner end of the taper surface, and causes the inner and outer seal members to closely contact with the flexible tube.

The chemical liquid supplying apparatus according to the present invention further comprises a wedge sleeve inserted inside the fastening cylindrical body from an opening end of the pump housing under the condition that the flexible tube is incorporated into the pump housing and that the fastening cylindrical body is incorporated into the end portion, wherein the wedge sleeve causes the fastening cylindrical body to be radially expanded so as to incline by being centered about an inner end of the taper surface, and forms, in the flexible tube, a folding portion that is folded by the outer and inner concave-convex portions. The chemical liquid supplying apparatus according to the present invention further comprises a check valve provided in the fastening cylindrical body.

According to the present invention, the outer surface of the end portion of the flexible tube is sealed by the outer seal member, and its inner surface is sealed by the inner seal member. Therefore, without welding the end portion of the flexible tube to the pump housing, a seal property is enhanced between the inner and outer surfaces of the end portion of the flexible tube, and a leakage of the chemical liquid or indirect medium can be prevented. Accordingly, both end portions of the flexible tube can adopt the fastening type, and the pump housing and the flexible tube can be manufactured using different materials. For example, the pump housing may be made of a metal material, and the flexible tube may be made of a resin material.

According to the present invention, under the condition that the flexible tube is incorporated into the pump housing and that the fastening cylindrical body is incorporated into the end portion of the flexible tube, the fastening cylindrical body is radially expanded by inserting the wedge sleeve inside the fastening cylindrical body which is incorporated into the end portion, and the outer and inner seal members are crushed and caused to closely contact with the end portion of the flexible tube, whereby the seal property can be enhanced. According to the present invention, the fastening cylindrical body is radially expanded by the wedge sleeve, and the folding portion is formed between the fastening cylindrical portion and the pump housing in the flexible tube, whereby the seal property of the end portion of the flexible tube can be enhanced.

According to the present invention, since the seal property of the flexible tube can be enhanced, durability of the flexible tube can be enhanced, and discharge accuracy can be also enhanced.

According to the present invention, since the check valve can be incorporated into the pump housing, the chemical liquid supplying apparatus can be downsized in comparison to a case where the check valve is disposed outside the pump housing. According to the present invention, since the end portion of the flexible tube is firmly fixed to the pump housing, even if a diameter of the flexible tube is set larger than its length, the flexible tube can be prevented from being offset and released from the fastening portion by the tension applied to the flexible tube during the pump operation. Therefore, the discharge accuracy can be enhanced, and the durability of the flexible tube can be improved.

### BRIEF DESCRIPTION OF THE DRAWINGS

FIG. 1A is an elevational view of a chemical liquid supplying apparatus according to one embodiment of the present invention;

FIG. 1B is a bottom view of FIG. 1A;

FIG. 2 is a sectional view showing an enlarged portion of FIG. 1A;

FIG. 3 is a sectional view showing an enlarged inflow-side end portion of a pump housing;

FIG. 4 is a sectional view showing an enlarged outflow-side end portion of the pump housing;

FIG. 5A is a sectional view showing an assembling procedure of a fastening cylindrical body and a wedge sleeve;

FIG. 5B is a sectional view showing an assembling procedure of the fastening cylindrical body and the wedge sleeve; and

FIG. 6 is a sectional view showing a chemical liquid supplying apparatus according to another embodiment of the present invention.

### DESCRIPTION OF THE PREFERRED EMBODIMENTS

Hereinafter, embodiments of the present invention will be described in detail based on the accompanying drawings.

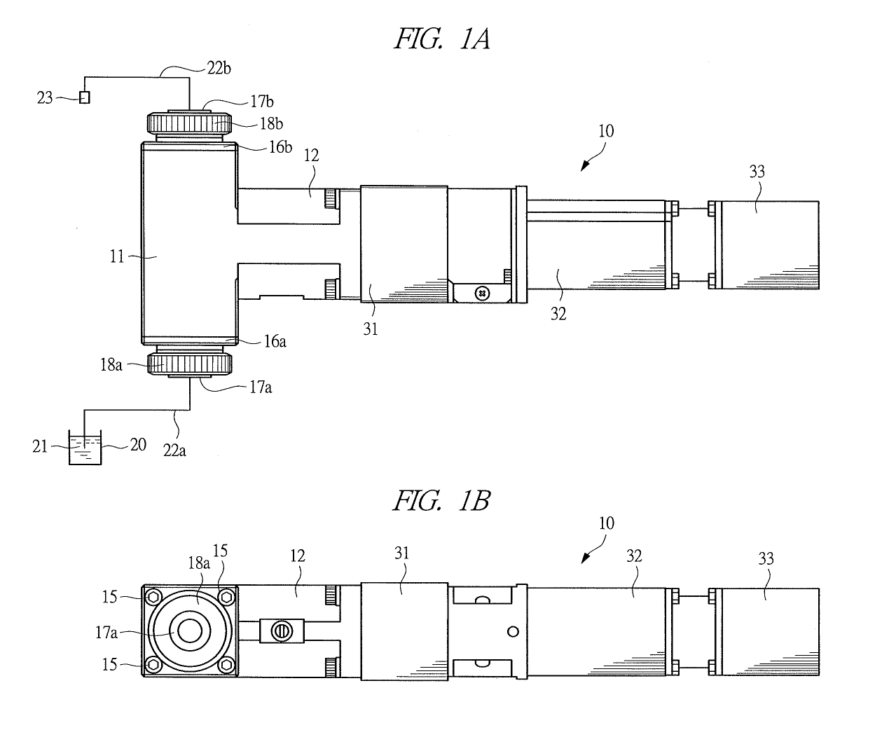

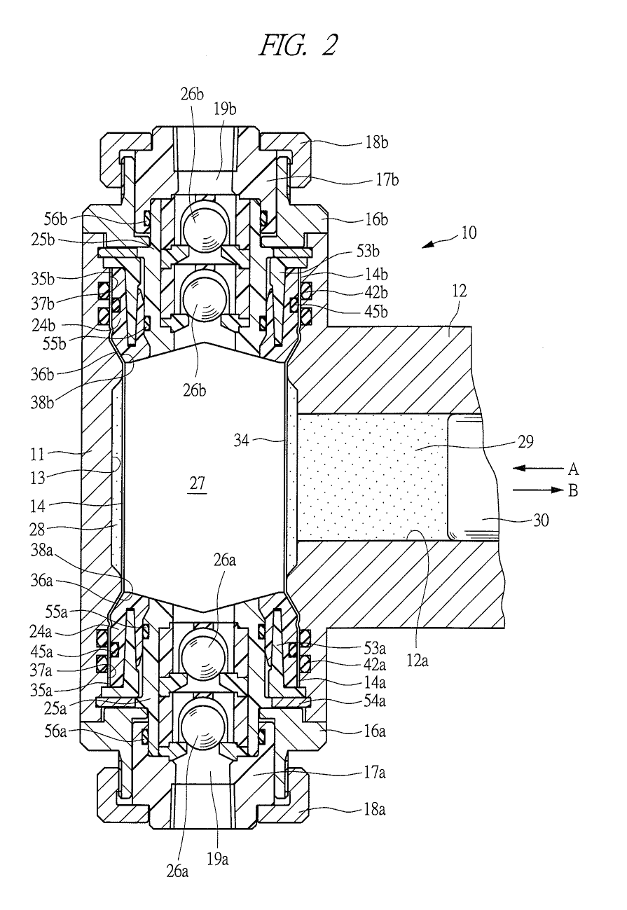

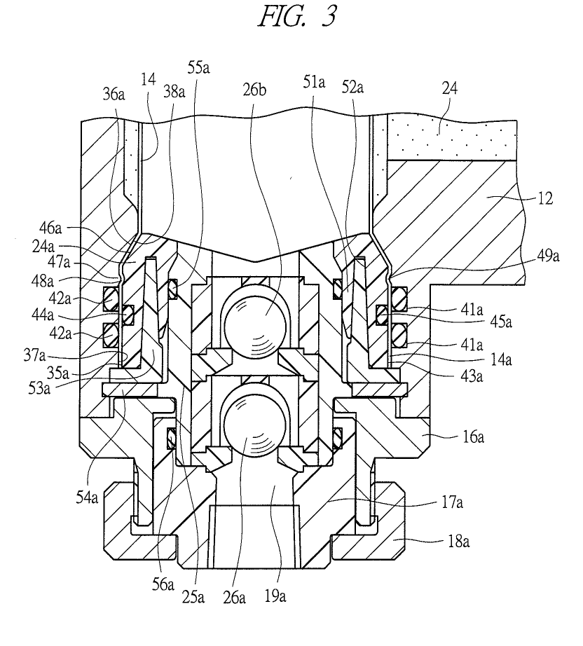

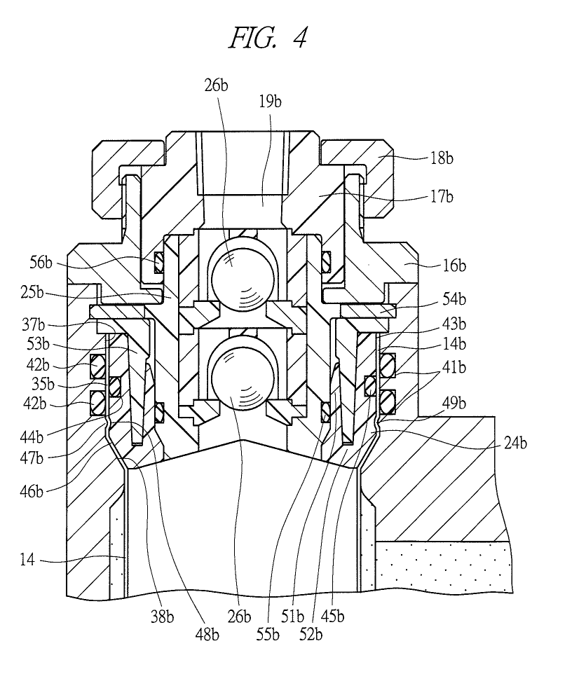

FIG. 1A is an elevational view of a chemical liquid supplying apparatus according to one embodiment of the present invention; FIG. 1B is a bottom view of FIG. 1A; FIG. 2 is a sectional view showing an enlarged portion of FIG. 1A; FIG. 3 is a sectional view showing an enlarged inflow-side end portion of a pump housing; and FIG. 4 is a sectional view showing an enlarged outflow-side end portion of the pump housing.

This chemical liquid supplying apparatus 10 includes a metal-made pump housing 11 whose outline is a substantial rectangular parallelepiped shape. Side walls of the pump housing 11 are provided integrally with a cylinder portion 12, and the cylinder portion 12 protrudes laterally with respect to the pump housing 11. As shown in FIG. 2, a through-hole 13 is formed in the pump housing 11 so as to penetrate longitudinally, and a cylindrical flexible tube 14 is incorporated in the through-hole 13. Both ends of the pump housing 11 are opened. As shown in FIG. 1B, a joint bracket 16a is attached to one end portion of the pump housing 11 by bolts 15, and an inflow-side connector 17a is fixed to the joint bracket 16a by a retaining nut 18a. An outflow-side connector 17b is fixed, by a retaining nut 18b, to a joint bracket 16b which is attached to the other end portion of the pump housing 11 by bolts. The inflow-side connector 17a has a liquid inlet 19a communicating with an interior of the flexible tube 14, and the outflow-side connector 17b has a liquid outlet 19b communicating with the interior of the flexible tube 14.

As shown in FIG. 1A, intended to be connected to the inflow-side connector 17a is a supply-side flow path 22a which guides chemical liquid 21 such as photoresist liquid accommodated in a chemical liquid tank 20. Meanwhile, a discharge-side flow path 22b is intended to be connected to the outflow-side connector 17b, and a tip of the discharge-side flow path 22b is provided with a nozzle 23 which discharges the chemical liquid 21. When the chemical liquid supplying apparatus 10 is used for a polishing apparatus for polishing and processing a surface of a semiconductor wafer, polishing liquid is applied as the chemical liquid 21 to the semiconductor wafer from the nozzle 23. When the chemical liquid supplying apparatus 10 is used for an apparatus of forming circuit patterns, photoresist or washing liquid is applied as the chemical liquid to the semiconductor wafer from the nozzle 23.

As shown in FIG. 2, an inflow-side end portion 14a of the flexible tube 14 is fixed to the one end portion of the pump housing 11 by a fastening cylindrical body 24a, and an outflow-side end portion 14b of the flexible tube 14 is fixed to the other end portion of the pump housing 11 by a fastening cylindrical body 24b. Cylindrical valve holders 25a and 25b are incorporated into the fastening cylindrical bodies 24a and 24b, respectively, and the valve holders 25a and 25b are provided with two check valves 26a and two check valves 26b, respectively.

The flexible tube 14, fastening cylindrical bodies 24a and 24b, and valve holders 25a and 25b are formed of fluorine resins which are materials not reacting with the chemical liquid 21 such as photoresist liquid. As such a fluorine resin, polytetrafluoroethylene (PTFE) or fluoroethylene perfluoro alkyl vinyl ether copolymer (PFA) has been used. However, the above materials can be variously selected according to a kind of the chemical liquid.

A pump chamber 27 inside and a drive chamber 28 outside the flexible tube 14 are partitioned by the flexible tube 14, and a portion of the flexible tube 14 located between the fastening cylindrical bodies 24a and 24b deforms radially elastically, thereby performing a pumping operation. The drive chamber 28 communicates with a cylinder hole 12a formed in the cylinder portion 12, and an incompressible, indirect medium 29 is enclosed inside the drive chamber 28 and the cylinder hole 12a. A piston 30 is mounted axially reciprocably in the cylinder hole 12a. When the piston is driven in a direction “A” as shown in FIG. 2, an elastically deformable portion of the flexible tube 14 contracts radially, whereby the pump chamber 27 contracts. Therefore, the chemical liquid in the pump chamber 27 passes the check valve 26b, and is discharged via the discharge-side flow path 22b from the liquid outlet 19b toward the nozzle 23. At this time, the chemical liquid in the pump chamber 27 is prevented from flowing back into the chemical liquid tank 20 by the check valve 26a.

Meanwhile, when the piston 30 is driven in a direction “B” as shown in FIG. 2, the elastically deformable portion of the flexible tube 14 expands radially, whereby the pump chamber 27 expands. Therefore, the chemical liquid in the chemical liquid tank 20 flows in the pump chamber 27 via the support-side flow path 22a. At this time, the chemical liquid in the discharge-side flow path 22a is prevented from flowing toward the pump chamber 27 by the check valve 26b.

Thus, the piston 30 serves as driving means for expanding/contracting the pump chamber 27 via the incompressible, indirect medium 29, and, to reciprocate axially the piston 30, as shown in FIG. 1, a drive unit 32 is attached to the cylinder portion 12 of the pump housing 11 via a connecting case 31. The drive unit 32 includes a ball screw rotationally driven by a main shaft of an electric motor 33, and a threaded shaft screwed to the ball screw and reciprocating axially, whereby the threaded shaft is coupled to the piston 30 of the cylinder portion 12.

As shown in FIG. 2, the center portion of the flexible tube 14 serves as the elastically deformable portion 34, and the inflow-side end portion 14a includes: a straight section 35a larger in diameter than the elastically deformable portion 34 under the condition that the elastically deformable portion 34 is not subjected to a radial-directional exterior force due to the indirect medium 29; and a taper section 36a between the elastically deformable portion 34 and the straight section 35a. A fitting hole, in which the end portion 14a is fitted, is formed in the pump housing 11, and the fitting hole has a straight hole 37a corresponding to the straight section 35a, and a taper hole 38a corresponding to the taper section 36a. The outflow-side end portion 14b of the flexible tube 14 includes, similarly to the end portion 14a, a straight section 35b larger in diameter, and a taper section 36b between the elastically deformable portion 34 and the straight section 35b, wherein a fitting hole, in which the end portion 14b is fitted, is formed in the pump housing 11. This fitting hole has a straight hole 37b corresponding to the straight section 35b, and a taper hole 38b corresponding to the taper section 36b.

As shown in FIG. 3, two annular grooves 41a are formed in an inner circumferential surface of the straight hole 37a, and an outer seal member 42a serving as an O-ring is disposed in each of the annular grooves 41a. The outer seal member 42a prevents the indirect medium 29 from leaking out from between the end portion 14a of the flexible tube 14 and the pump housing 11. Similarly, as shown in FIG. 4, two annular grooves 41b are formed in an inner circumferential surface of the straight hole 37b, and an outer seal member 42b serving an O-ring is disposed in each of the annular grooves 42b. The outer seal member 42b prevents the indirect medium 29 from leaking out from between the end portion 14b of the flexible tube 14 and the pump housing 11.

As shown in FIG. 3, an annular groove 44a is formed in a straight outer circumferential surface 43a corresponding to the straight section 35a of the flexible tube 14 within an outer circumferential surface of the fastening cylindrical body 24a, and an inner seal member 45a composed of an O-ring is disposed in the annular groove 44a. The inner seal member 45a prevents the chemical liquid from leaking out from between the end portion 14a of the flexible tube 14 and the fastening cylindrical body 24a. Similarly, as shown in FIG. 4, an annular groove 44b is formed in a straight outer circumferential surface 43b corresponding to the straight section 35b of the flexible tube 14 within an outer circumferential surface of the fastening cylindrical body 24b, and an inner seal member 45b composed of an O-ring is disposed in the annular groove 44b. The inner seal member 45b prevents the chemical liquid from leaking out from between the end portion 14b of the flexible tube 14 and the fastening cylindrical body 24b.

As shown in FIG. 3, a taper outer circumferential surface 46a is formed in an axial-directional inner end portion of the fastening cylindrical body 24a so as to correspond to the taper hole 38a. Similarly, as shown in FIG. 4, a taper outer circumferential surface 46b is formed in an axial-directional inner end portion of the fastening cylindrical body 24b so as to correspond to the taper hole 38b. Accordingly, when the fastening cylindrical bodies 24a and 24b are incorporated into the end portions 14a and 14b of the flexible tube 14 in a state of causing the taper outer circumferential surfaces 46a and 46b to abut on the taper holes 38a and 38b, the straight outer circumferential surfaces 43a and 43b of the fastening cylindrical bodies 24a and 24b are pushed toward the straight holes 37a and 37b. Therefore, the outer seal members 42a and 42b and the inner seal members 45a and 45b are caused to closely contact with the end portions 14a and 14b of the flexible tube 14, respectively, whereby a seal property is ensured between them.

As shown in FIGS. 3 and 4, projection portions 47a and 47b, which protrude radially inward and serve as outer concave-convex portions, are formed in the inner circumferential surfaces of the straight holes 37a and 37b of the pump housing 11, and annular grooves 48a and 48b serving as inner concave-convex portions are formed in the straight outer circumferential portions 43a and 43b of the fastening cylindrical bodies 24a and 24b so as to correspond to the projection portions 47a and 47b, respectively. Accordingly, when the fastening cylindrical bodies 24a and 24b are fitted in the end portions 14a and 14b, folding portions 49a and 49b, which have been folded by the projection portions 47a and 47b and the annular grooves 48a and 48b, are formed in the straight sections 35a and 35b of the flexible tube 14. By the folding portions 49a and 49b, the indirect medium 29 and the chemical liquid 21 are prevented from leaking out. Also, the flexible tube 14 can be tightly fixed.

Incidentally, by inverting a concave-convex relation between the outer concave-convex portion and the inner concave-convex portion, annular grooves serving as outer concave-convex portions may be formed in the inner circumferential surfaces of the straight holes 37a and 37b, and projection portions serving as inner concave-convex portions may be formed in the straight outer circumferential surfaces 43a and 43b.

As shown in FIGS. 3 and 4, guide cylindrical bodies 51a and 51b, which are formed into cylindrical shapes, are provided inside the fastening cylindrical bodies 24a and 24b, respectively, and the guide cylindrical bodies 51a and 51b are integrated with the fastening cylindrical bodies 24a and 24b at their inner-axial ends, respectively. Between the guide cylindrical bodies 51a and 51b and the fastening cylindrical bodies 24a and 24b, guide grooves 52a and 52b which have taper shapes are formed respectively so that gaps therebetween are gradually increased toward an opening portion of the pump housing 11. Cylindrical wedge sleeves 53a and 53b, which have taper shapes correspondingly to the guide grooves 52a and 52b, are intended to be inserted into the guide grooves 52a and 52b, and the wedge sleeves 53a and 53b are fixed respectively to the pump housing 11 by stopper rings 54a and 54b which are engaged with the annular grooves formed in the pump housing 11.

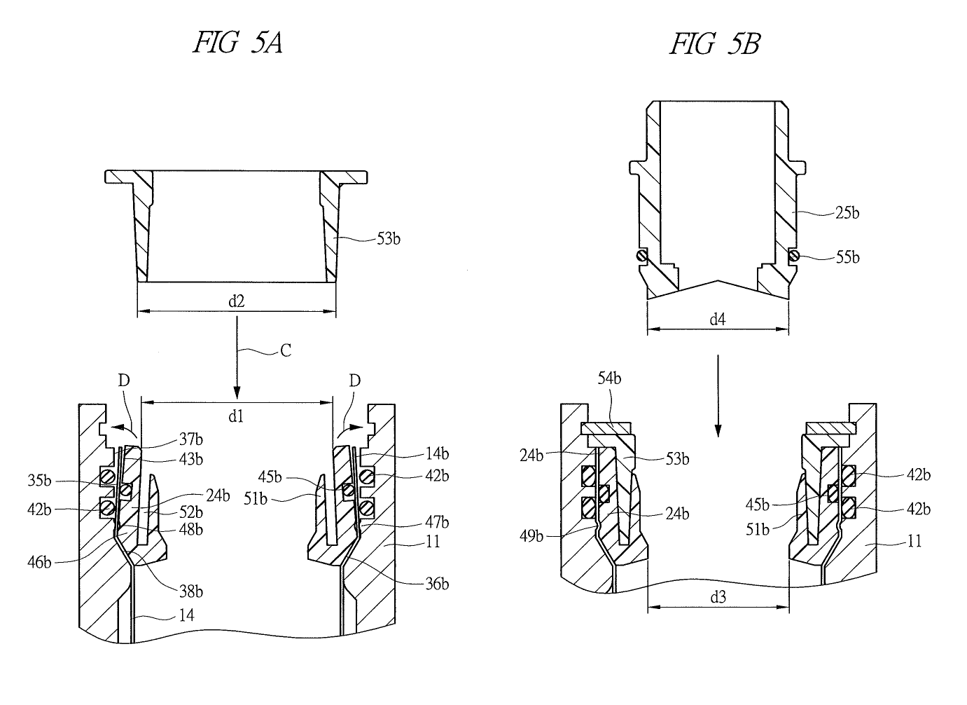

FIGS. 5A and 5B are sectional views showing an assembling procedure of the fastening cylindrical body 24b and the wedge sleeve 53b. As shown by an arrow “C” in FIG. 5A, under the condition that the flexible tube 14 is incorporated into the pump housing 11, and that the fastening cylindrical body 24b is incorporated into the end portion 14b of the flexible tube 14, the wedge sleeve 53b is inserted inside the fastening cylindrical body 24b from an opening end portion of the pump housing 11. When the fastening cylindrical body 24b integrated with the guide cylindrical body 51b is shaped (molded) by a resin material, an outer diameter on an outer-axial end side as shown in FIG. 5A is smaller in size than that of an inner-axial end side. At this time, an inner diameter “d1” of an outer end of the fastening cylindrical body 24b is substantially equal to or slightly smaller than a tip-side outer diameter “d2” of the wedge sleeve 53b.

When the wedge sleeve 53b is inserted, a diameter of the fastening cylindrical body 24b is expansively changed by being centered about its inner-axial end in a direction of inclining radially outwards as shown by an arrow “D” in FIG. 5A. Therefore, the outer seal members 42b and the inner seal member 45b are radially crushed and are elastically deformed as shown in FIG. 5B, and are caused to closely contact with the end portion 14b of the flexible tube 14, whereby the seal property is enhanced between the indirect medium 29 and the chemical liquid 21. When the wedge sleeve 53b is inserted into the fastening cylindrical body 24b, the folding portion 49b is further formed in the end portion 14b due to the projection portion 47b and the annular groove 48b, whereby the seal property is enhanced between the indirect medium 29 and the chemical liquid 21 also by the folding portion 49b. Particularly, in the wedge sleeve 53b, since the inner-axial end portion is narrow and its outer circumferential surface is tapered, an inserting force of the wedge sleeve 53b is increased due to a wedge effect, whereby the folding portion 49b can be certainly formed, by the weak inserting force, in the flexible tube 14 which is made of a hard resin. As shown in FIG. 5B, The wedge sleeve 53b is fixed to the pump housing 11 by the stopper ring 54b.

After the wedge sleeve 53b is attached to the pump housing 11 in a manner as described above, as shown in FIG. 5B, the valve holder 25b is incorporated inside the end portion 14b of the flexible tube 14. An inner diameter of “d3” of an inner-axial end of the guide cylindrical body 51b is substantially equal to a tip-side outer diameter “d4” of the valve holder 25b, and when the valve holder 25b is fitted inside the guide cylindrical body 51b, the chemical liquid 21 is prevented from leaking out from between the valve holder 25b and the guide cylindrical body 51b by a seal member 55b provided to the valve holder 25b.

FIGS. 5A and 5b have each shown the fastening cylindrical body 24b and the wedge sleeve 53b which are incorporated into the end portion 14b of the flexible tube 14 located on a liquid-outflow side. However, the same structure as the above-mentioned one is adopted also regarding the end portion 14a located on a liquid-inflow side opposite to the end portion 14b, wherein, as shown in FIG. 3, the valve holder 25b is provided with a seal member 55a.

As shown in FIGS. 3 and 4, the check valves 26a and 26b are incorporated into the valve holders 25a and 25b, respectively, and the valve holders 25a and 25b and the check valves 26a and 26b are positioned by the connectors 17a and 17b and fixed by the retaining nuts 18a and 18b. Thus, the check valves 26a and 26b are incorporated into the pump housing 11, whereby the chemical liquid supplying apparatus 10 including the check valves can be downsized in dimension. The connectors 17a and 17b are provided with seal members 56a and 56b for preventing a leakage of the chemical liquid 21 which passes through check valves 26a and 26b.

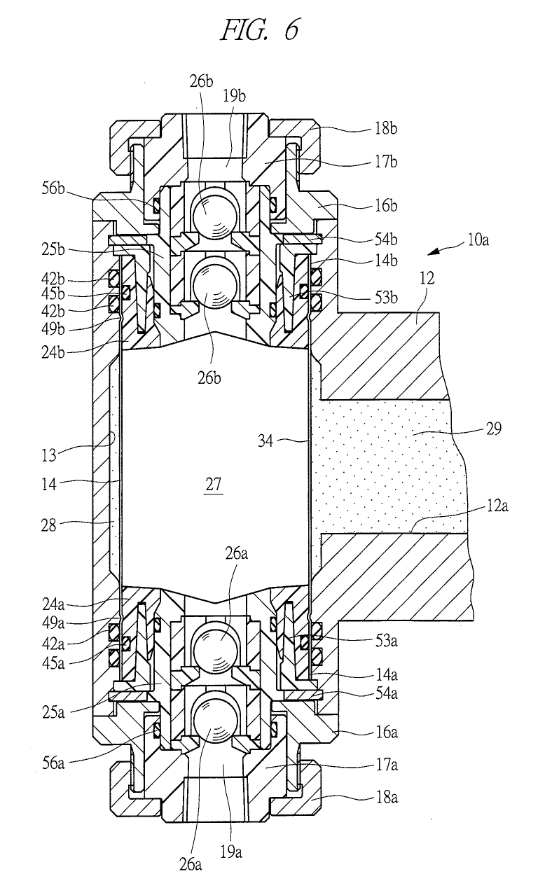

FIG. 6 is a sectional view showing a chemical liquid supplying apparatus 10a according to another embodiment of the present invention. The both end portions 14a and 14b of the flexible tube 14 in this chemical liquid supplying apparatus 10a are different from those of the chemical liquid supplying apparatus 10 as shown in FIG. 2, and have the same diameter as that of the elastically deformable portion 34. Thus, even if elements constituting the flexible tube 14 overall have the same diameter, when the wedge sleeves 53a and 53b are inserted inside the fastening cylindrical bodies 24a and 24b from an opening end of the pump housing 11 under the condition that the flexible tube 14 and incorporated into the pump housing 11 and that the fastening cylindrical bodies 24a and 24b are incorporated into the end portions 14a and 14b, the fastening cylindrical bodies 24a and 24b radially expand so as to incline by being centered about respective inner ends of the fastening cylindrical bodies, and the inner seal members 45a and 45b and the outer seal members 42a and 42b closely contact with to the flexible tube 14, respectively, whereby the seal property can be enhanced therebetween. In addition thereto, since the folding portions 49a and 49b are formed in the flexible tube 14, the seal property can be further enhanced.

If the straight sections 35a and 35b and the taper sections 36a and 36b are provided to the both end portions 14a and 14b similarly to the flexible tube 14 of the chemical liquid supplying apparatus 10 shown in FIG. 2, the taper sections 36a and 36b are fastened by pushing and inserting the fastening cylindrical bodies 24a and 24b into the pump housing 11, whereby the seal property is enhanced. Further, when the wedge sleeves 53a and 53b are inserted inside the fastening cylindrical bodies 24a and 24b, since the fastening cylindrical bodies 24a and 24b are positioned by the taper sections 36a and 36b, inserting operations of the wedge sleeves 53a and 53b become easy.

Thus, as shown in FIGS. 2 and 6, the flexible tube 14 made of a hard resin such as a fluorine resin can be firmly fixed to the metal pump housing 11 while the seal property therebetween is being ensured. Such firm fixture as mentioned above can prevent the flexible tube from being offset and released from the fastening portion due to the tension applied to the flexible tube during the pumping operation, whereby the discharge accuracy can be enhanced, and the durability of the flexible tube can be improved.

As a modification of the chemical liquid supplying apparatus, there is a type in which the folding portions 49a and 49b are provided on an axial-directional outer side with respect to the outer seal members 42a and 42b. Further, as shown in FIG. 2, if the taper sections 36a and 36b are provided to the flexible tube 14, there is a type in which at least one set of the inner seal members and the outer seal members is caused to closely contact with the taper sections 36a and 36b.

The present invention is not limited to the above embodiments, and can be variously altered and modified within a scope of not departing from the gist thereof. For example, driving means for expanding and contracting the pump chamber 27 is not limited to the piston 30, and a bellows or diaphragm may be used as the above means.

What is claimed is:

1. A chemical liquid supplying apparatus comprising:
a pump housing provided with a liquid inlet and a liquid outlet;
a flexible tube incorporated into the pump housing, partitioning a pump chamber communicating with the liquid inlet and outlet, and partitioning a drive chamber in which an incompressible, indirect medium is enclosed between the flexible tube and the pump housing;
driving means provided to the pump housing, and expanding and contracting the pump chamber via the incompressible, indirect medium;
an outer seal member disposed in an inner surface of the pump housing so as to correspond to an end portion of the flexible tube;
a fastening cylindrical body, outside which an inner seal member is provided and which is disposed in the end portion of the flexible tube; and
a wedge sleeve inserted inside the fastening cylindrical body from an opening end of the pump housing under the condition that the flexible tube is incorporated into the pump housing and that the fastening cylindrical body is incorporated into the end portion, the wedge sleeve causing the fastening cylindrical body to be radially expanded so as to incline by being centered about an inner end of the fastening cylindrical body, and causing the inner and outer seal members to closely contact with the flexible tube.

2. The apparatus according to claim 1,
wherein an outer concave-convex portion is formed in the inner surface of the pump housing so as to correspond to the end portion of the flexible tube,
an inner concave-convex portion is formed in the fastening cylindrical body so as to correspond to the outer concave-convex portion, and
a folding portion, which is folded by the outer and inner concave-convex portions when the wedge sleeve is inserted inside the fastening cylindrical body, is formed in the flexible tube.

3. A chemical liquid supplying apparatus comprising:
a pump housing provided with a liquid inlet and a liquid outlet;
a flexible tube incorporated into the pump housing, partitioning a pump chamber communicating with the liquid inlet and outlet, and partitioning a drive chamber in which an incompressible, indirect medium is enclosed between the flexible tube and the pump housing;
driving means provided to the pump housing, and expanding and contracting the pump chamber via the incompressible, indirect medium;
an outer seal member disposed in a fitting hole, which is formed in an inner surface of the pump housing, so as to correspond to an end portion having a straight hole larger in diameter than an elastically deformable portion which is a center portion of the flexible tube, and a taper hole located between the elastically deformable portion and the straight hole; and
a fastening cylindrical body having a straight outer circumferential surface corresponding to the straight hole and a taper outer circumferential surface corresponding to the taper hole, an outer circumferential surface of the fastening cylindrical body being provided with an inner seal member, and the fastening cylindrical body being disposed in the end portion of the flexible tube,
wherein the flexible tube is fastened between the taper outer circumferential surface and the taper hole, and
the straight outer circumferential surface is pushed to the straight hole so that the outer and inner seal members are caused to closely contact with the flexible tube.

4. The apparatus according to claim 3,
wherein an outer concave-convex portion is formed in an inner circumferential surface of the pump housing so as to correspond to the end portion of the flexible tube,
an inner concave-convex portion is formed in the fastening cylindrical body so as to correspond to the outer concave-convex portion, and
a folding portion, which is folded by the outer and inner concave-convex portions, is formed in the flexible tube.

5. The apparatus according to claim 3, further comprising a wedge sleeve inserted inside the fastening cylindrical body from an opening end of the pump housing under the condition that the flexible tube is incorporated into the pump housing and that the fastening cylindrical body is incorporated into the end portion,
wherein the wedge sleeve causes the fastening cylindrical body to be radially expanded so as to incline by being centered about an inner end of the taper surface, and causes the inner and outer seal members to closely contact with the flexible tube.

6. The apparatus according to claim 4, further comprising a wedge sleeve inserted inside the fastening cylindrical body from an opening end of the pump housing under the condition that the flexible tube is incorporated into the pump housing and that the fastening cylindrical body is incorporated into the end portion,
wherein the wedge sleeve causes the fastening cylindrical body to be radially expanded so as to incline by being centered about an inner end of the taper surface, and forms, in the flexible tube, a folding portion that is folded by the outer and inner concave-convex portions.

7. The apparatus according to claim 1, further comprising a check valve provided in the fastening cylindrical body.

8. The apparatus according to claim 3, further comprising a check valve provided in the fastening cylindrical body.
